(19) United States
(12) Patent Application Publication
(10) Pub. No.: US 2012/0186871 A1
(43) Pub. Date: Jul. 26, 2012

(54) Adjustable electrical box

(76) Inventor: John M. Roberts, Concord, NH (US)

(21) Appl. No.: 13/010,850

(22) Filed: Jan. 21, 2011

(51) Int. Cl. H05K 5/00; H05K 13/00

(52) U.S. Cl. 174/520; 29/592.1

(57) ABSTRACT

An adjustable electrical box includes a box element having an enclosure with a box perimeter wall, a back wall and a front opening, a box extender telescopically received in the box opening, the box extender having a tubular body with an extender perimeter wall, an open front, an open back, and a lateral outward flange connected to a portion of the open front and extending a distance no greater than to the perimeter of the box element, and a first stop member pivotally connected to the lateral outward flange where the first stop member pivots between a first non-engaging position and a second surface-engaging position.

### BACKGROUND OF THE INVENTION

1. Field of the Invention

The present invention relates generally to electrical boxes. Particularly, the present invention relates to electrical boxes and electrical box extensions.

2. Description of the Prior Art

Electrical boxes are commonly used to provide electrical service at convenient locations within buildings and to provide a termination for electrical connections to electrical components such as outlets and switches. Electrical boxes may be in the form of outlet boxes, junction boxes, floor boxes and switch boxes and may be located in walls, floors or ceilings or any location in which an electrical termination takes place. Electrical boxes are typically secured to a support structure such as a wall stud or ceiling joist. The support structure is then covered with a covering material such as gypsum board, plaster, paneling or other type of covering material. Electrical boxes are commonly formed of plastic or metal and are usually securely fastened by screws or nails to the framework within the building.

During new construction when electrical wiring is installed, electrical boxes are attached to the support structures in the desired location. When a box is secured to a support structure this typically fixes the position of the electrical box and does not provide for movement thereof. In the building industry, the positioning of electrical outlet boxes and the connections thereto are covered by a number of building code requirements. In general, these code requirements are set up to insure a good workmanlike assembly of the outlet box in the building, and to insure safety in the use of electrical receptacle plugs in the outlet box and the permanent satisfactory positioning of power supply leads connecting to the box and outlet receptacles positioned therein.

Thus, in the assembly of the outlet boxes in walls, if these walls are made of non-combustible material, the boxes should be installed so that the front edge of the box will not set back from the finished surface more than ¼ inch. In walls and ceilings constructed of wood or other combustible materials, the outlet boxes must be flush with the finished surface of or project from such wall premises. Yet, other portions of the building code require that plaster surfaces that are broken or incomplete adjacent the box shall be repaired so that there are no gaps or open spaces at the edge of the outlet box no greater than ⅛ inch.

Other portions of the building code require that where a fixture canopy or pan is used, any combustible wall or ceiling finish material exposed between the edge of the canopy or pan and the outlet box shall be covered with a non-combustible material. For non-metallic boxes, the code requires that the supports or other mounting means for non-metallic boxes must be outside of the box or the box must be constructed so as to prevent contact between the conductors in the box and any metallic means in the box.

For proper installation, the front edge of the electrical box is typically desired to be substantially flush with the covering material. For interior construction, when wall covering material having standard thicknesses is used, such as gypsum board, electrical boxes may include a fixed offset for alignment with the front edge of the support structure such that the front of the box extends beyond the support structure a certain distance. Hence, when the covering is attached the front of the box is substantially flush with the front surface of the wall covering. This fixed offset, however, requires that the installer know the thickness of the wall covering at the time of installation. The position cannot be easily adjusted to accommodate for covering materials of irregular thickness or situations in which the covering thickness is changed after the electrical box is installed.

To solve this problem, adjustable mounting assemblies for an electrical outlet box or box extenders of several different types have been developed. Adjustable mounting assemblies typically include a bracket which moves relative to the electrical box. With the bracket fixed to the support structure, adjustment results in the entire box moving. Accordingly, installation of such a box requires an installer to ensure that there is enough play in the electrical wiring such that movement does not cause undue stress on the wiring.

Regarding box extenders, one such box extender relies on a friction fit to hold the box extender in the existing electrical box. This extender has the disadvantage of not providing a secure attachment to the existing box, and the electrical device may slide further within the box making it hard to reach.

Another type of extender consists of an extension having walls of approximately the same configuration as the existing box and of fixed thickness. The extender is available in several thicknesses to accommodate several different sheet stock thicknesses. Although there are many thicknesses available, the extender sometimes is not of a proper thickness to bring the existing box flush with the new surface, and this creates an aesthetically undesirable appearance.

Another type of extender includes a body portion having at least one wall and open faces and a second open face. The extender includes side flanges having holes that align with brackets that are connected to the electrical box. This extender is difficult to use and install as brackets must be firmly attached to the electrical box and then two screws are used to attach each flange of the extender to the electrical box.

In yet another type of extender, the extender is a one-piece, plastic molded box having an open face member, an open back, flanges extending from the open face member and four wings extending from the inward side of the face member. The extender is inserted into an existing electrical box with the flanges being flush with the surface of the newly installed wall covering such as gypsum wallboard.

A supplemental part which is a variation of the electrical box extender can be used as a device insulator in those locations where a metal electrical box is used and an electrical device does not need to be extended to a new wall surface but rather where there is a limited amount of space to create a secure device which is not prone to shorting out. A typical example would be the installation of a GFCI device in an electrical box. The GFCI device is a bulky device that fits with little clearance into an electrical box. The terminals on the side of a GFCI are close fitting to the side of the metal electrical box and frequently the GFCI will be tripped when the terminals contact the side of the box. The supplemental part is inserted within an existing electrical box to act as a device insulator and keep bulky electrical devices insulated from the surrounding metal electrical box.

### SUMMARY OF THE INVENTION

As discussed above, installation of electrical boxes are typically installed on the support structure so that the front of the box extends beyond the support structure a certain distance in new construction. Even though the electrical code allows up to a ¼ inch set back of the wall covering from the front of the electrical box when the wall covering is made of a non-combustible material, code enforcement officers in many locations are requiring the stricter flush fit requirement. Electrical contractors are faced with either appealing the code enforcement officer's stricter requirement, which is timely and costly, or they capitulate and install the box extenders in order to obtain the code officer's approval and the subsequent and necessary occupancy permit. In any event, whether it's to satisfy a code enforcement officer or that the wall covering is made of a combustible material, the electrical contractor must return to install box extenders in those electrical boxes after the wall covering is applied.

The disadvantage to this process is the added time and expense to accommodate this requirement. Because most box extenders have openings for receiving the screws therethrough that attach the outlet to the electrical box, the electrical contractor must disconnect the outlet screws from the electrical box, move the outlet outward from the electrical box beyond the facing of the wall covering, insert the box extender over the outlet and into the electrical box until the box extender flange butts up against the facing of the wall covering, then re-attaching the screws of the outlet or switch to the electrical box. Not only does this add labor expense to the job but, additionally, the box extenders are typically much more expensive than the electrical box originally installed.

Another disadvantage of these after-market box extenders is that they typically fit loosely within the electrical box since they must be of a dimension that can be used in electrical boxes of various manufacturers, whose electrical box dimensions and design are slightly different from each other.

A further disadvantage of these loosely fitting box extenders is that the space between the surface openings in the wall covering surrounding the electrical box and the perimeter of the electrical box cannot be sealed to prevent heat loss. A ⅛ inch space is allowed under the Electrical Code between the perimeter of the electrical box and the surface opening in the wall covering. This space is a source of heat loss when heating the room interior or a source of heat gain when cooling the room interior. Sealing this space saves natural resources since less energy is required to heat or cool the room if the electrical boxes and the wall covering openings are sealed with a thermal insulating material. An example of one thermal insulating material usable with the invention is a urethane foam sealant sold under the mark Great Stuff™ by Dow Chemical Company of Wilmington, Ill., which is a window and door insulating foam sealant. Because the typical prior art box extender is loose fitting in an electrical box, spraying insulating foam sealant in the space between the wall covering and the electrical box would enter the electrical box through the space between the perimeter wall of the loose fitting box extender and the inside surface of the perimeter wall of the electrical box. The Electrical Code does not allow for the addition of any material to the inside of the electrical box other than the power cable, outlet and/or switch.

The above-described extenders and supplemental parts of the prior art have not proven fully satisfactory for extending electrical boxes flush with the new walls or ceilings in new construction or in a renovated or restored building.

It is an object of the present invention to provide an electrical box that is more cost efficient when the electrical box needs to be extended. It is another object of the present invention to provide an electrical box that allows the space around the electrical box and a wall covering opening to be sealed with insulating foam sealant.

The present invention achieves these and other objectives by providing an adjustable electrical box with a box extender configured to allow the use of an insulating foam sealant around the perimeter of the electrical box while minimizing the amount of foam sealant that enters into the interior of the electrical box. In one embodiment of the present invention, there is provided an adjustable electrical box including a box element having an enclosure with a box perimeter wall, a back wall and a front opening, a box extender having a tubular body telescopically received in the box opening, and a first stop member pivotally connected to the box extender. The tubular body has an extender perimeter wall, an open front, an open back, and a lateral outward flange connected to a portion of the open front and extending a distance no greater than to the perimeter of the box element. The first stop member is pivotally connected to the lateral outward flange of the box extender where the first stop member pivots between a first non-engaging position and a second surface-engaging position.

In another embodiment of the present invention, the extender perimeter wall includes a back wall, a top wall, a bottom wall, and a pair of opposed sidewalls. The lateral outward flange is connected to a portion of one or more locations on the open front of the box extender selected from the group consisting of the top side, the bottom side, the first opposed side, and the second opposed side.

In a further embodiment of the present invention, the box extender includes a second stop member pivotally connected to the lateral outward flange wherein the second stop element pivots between a first-engaging position and a second non-engaging position. The second stop member is located on a portion of the lateral outward flange that is opposite the position of the first stop element.

In still another embodiment of the present invention, the box element of the adjustable electrical box has a berm member located on one or more of an inside surface of the box perimeter wall of the box element. In one embodiment where the box perimeter wall has a plurality of defined walls, the berm member may be located on one or more of an inside surface of box element selected from the group consisting of a top wall, a bottom wall, and one of a pair of opposed sidewalls. The berm member is positioned to provide a releasable interference fit with an outside surface of the box extender.

In yet another embodiment of the present invention, the box extender has a berm member located on an outside surface of the tubular body. The berm member is positioned to provide a releasable interference fit with an inside surface of the box element.

In another embodiment of the present invention, the box extender has a berm member located on one or more of an outside surface selected from the group consisting of a top side, a bottom side, a first opposed side, and a second opposed side.

In another embodiment of the present invention, the extender perimeter wall has a sliding fit to the box perimeter wall sufficiently close to allow the application of an insulating foam sealant between the box element and an edge of a wall covering opening that exposes the opening of the box element while minimizing penetration of the insulating foam sealant to the interior of the box element.

In a further embodiment of the present invention, the first opposed side and the second opposed side of the box extender has a sliding fit to the pair of opposed sidewalls of the box element sufficiently close to allow the application of an insulating foam sealant between the box element and an edge of a surface opening that exposes the opening of the box element while minimizing penetration of the insulating foam sealant to the interior of the box element.

In another embodiment of the present invention, the stop element has an outer surface that aligns with an outer surface of the lateral outward flange of the box extender.

In a further embodiment of the present invention, there is disclosed an electrical box extender configured for being telescopically received in the box opening of an electrical box. The box extender has a tubular body that includes an extender perimeter wall, an open front, an open back, and a lateral outward flange connected to a portion of the open front and extending a distance no greater than to the perimeter of the box element. The first stop member pivots between a first non-engaging position and a second surface-engaging position.

In another embodiment, there is disclosed a method of efficiently extending an electrical box opening flush with a wall covering. The method includes providing an electrical box for new construction installation that includes a box element forming an enclosure with a front opening, a box extender telescopically received in the box front opening, and a first stop member pivotally connected to a lateral outward flange of the box extender where the first stop member pivots between a first non-engaging position and a second surface-engaging position, attaching the electrical box to a wall stud and installing electrical wiring to the electrical box, applying a wall covering to the wall stud and creating an opening for exposing the electrical box and electrical wiring, sliding the box extender outwardly from the box until the lateral outward flange is beyond the wall surface, pivoting the first stop member from the first non-engaging position to the second surface-engaging position, sliding the box extender inwardly into the box until the first stop member engages the surface of the wall covering, and coupling an electrical component to the electrical wiring and to the electrical box.

In a further embodiment of the method, the method includes sealing the space between the electrical box and the edge of the opening in the wall covering with an insulating foam sealant minimizing air and thermal flow between the space behind the wall covering and the room where the sliding fit between the box extender and the box element is sufficiently close to minimize the penetration of insulating foam sealant into the box element.

In another embodiment of the method of the present invention, the step of coupling the electrical component to the electrical box includes coupling the first stop member between a portion of the electrical component and the wall covering.

### BRIEF DESCRIPTION OF THE DRAWINGS

FIG. 1 is a perspective view of one embodiment of the present invention showing an electrical box with a box element and a box extender.

FIG. 2 is a rear perspective view of the embodiment of the present invention shown in FIG. 1.

FIG. 3 is a perspective view of the embodiment illustrated in FIG. 1 showing the box extender spatially separated from the box element.

FIG. 4 is a front view of the embodiment illustrated in FIG. 1.

FIG. 4A is a partial front view of the embodiment illustrated in FIG. 4 with the flange removed to show the berm on the outside surface of the box extender.

FIG. 5 is a side transparent view of the embodiment illustrated in FIG. 1 showing the box extender interfacing with a wall covering.

FIG. 6 is a perspective view of another embodiment of the present invention showing a modified box extender.

FIG. 7 is a front view of the embodiment illustrated in FIG. 6

FIG. 8 is an enlarged, partial perspective view of the box extender showing a stop member with an outer surface aligned with the outer surface of the lateral outward flange.

### DETAILED DESCRIPTION OF THE PREFERRED EMBODIMENT

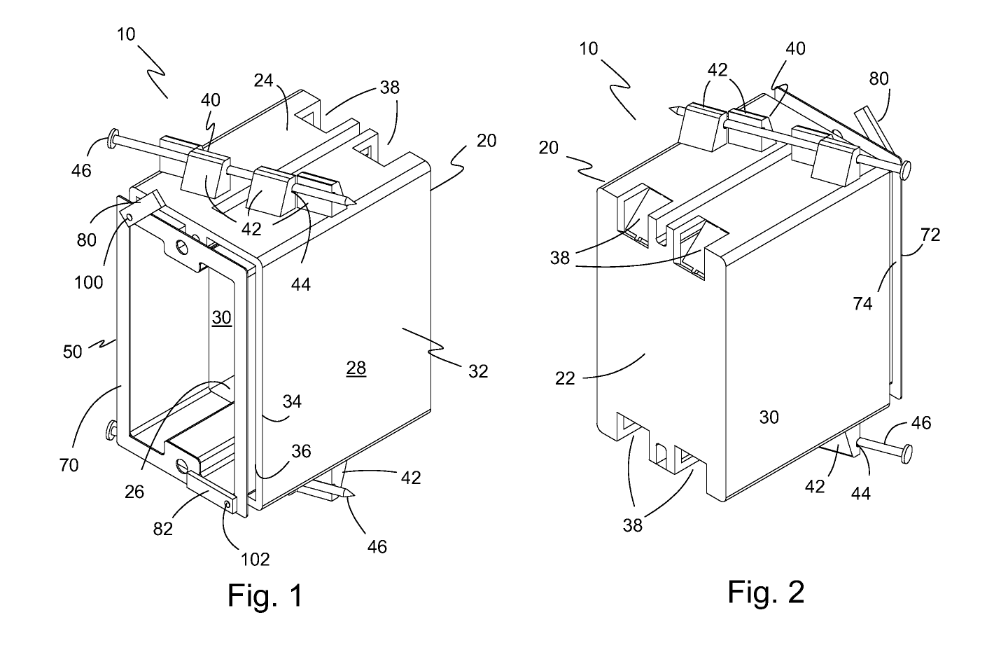

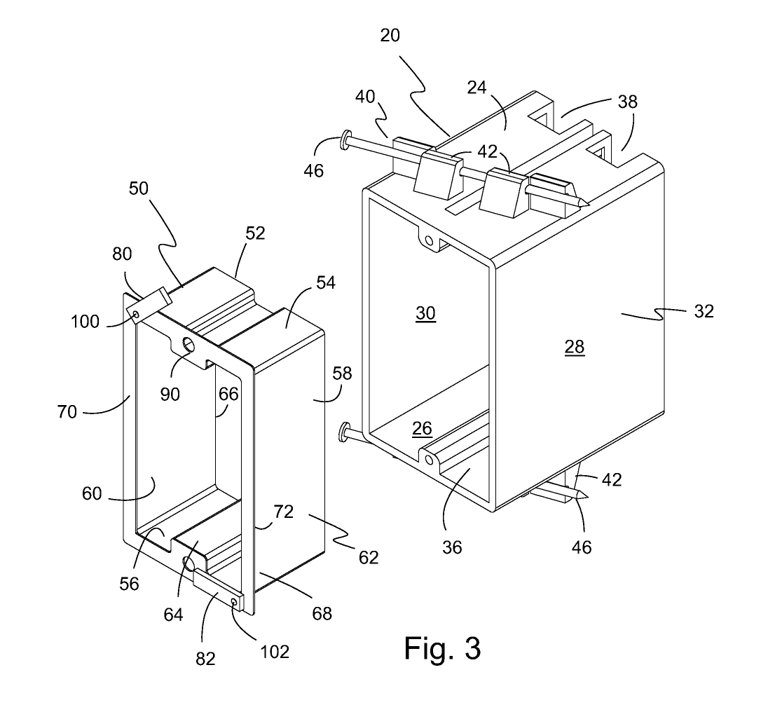

The preferred embodiment(s) of the present invention is illustrated in FIGS. 1-8. FIGS. 1-3 illustrate one embodiment of an adjustable electrical box 10 of the present invention. Electrical box 10 includes a box element 20, a box extender 50 and a first stop member 80. Box element 20 includes a back wall 22 bounded by a top wall 24, a bottom wall 26, and a pair of opposed sidewalls 28, 30. Top wall 24, bottom wall 26 and opposed sidewalls 28, 30 are joined together to form a continuous perimeter wall 32 ending in a box edge 34. Box edge 34 defines a front opening 36 in to which electrical components and/or wires may extend. Box element 20 may be formed of metal, plastic or polymer material of the type typically used to make electrical boxes. Box element 20 may also include a plurality of knock-outs 38 formed on perimeter wall 32. For example, the knock-outs 38 may be formed on the perimeter wall 32 in order to permit electrical wiring to enter box element 20.

The present invention also provides a means such as securement device 40 of securing electrical box 10 to a support structure. Securement device 40 includes a plurality of ears 42 extending outwardly from top wall 24 and bottom wall 26 of box element 20. Each of ears 42 includes a slot 44 which accommodates a fastener 46. Such fasteners may be frictionally held within slots 44. This frictional retention may be overcome by hammering fasteners 46 into the support structure upon installation.

Telescopically received within box opening 36 is box extender 50. Box extender 50 has a tubular body 52 with top side 54, a bottom side 56, a first opposed side 58, and a second opposed side 60 interconnected to form an extender perimeter wall 62, having a configuration substantially similar to the configuration of the inside surface of perimeter wall 32. For example, in the preferred embodiment, box perimeter wall 32 and extender perimeter wall 62 both have a rectangularly-shaped opening. It is contemplated, however, that box element 20 and box extender 50 may be formed in a variety of complementary shapes including, but not limited to, circular, oval, square, octagonal, etc. Box extender 50 also includes an open front 64 and an open back 66. Perimeter wall 62 has a front portion 68 having a lateral outward flange 70 which ends in a flange edge 72. Flange 70 extends outwardly from a portion of perimeter wall 62 forming a ridge 74. Lateral flange 70 is connected to one or more locations on front portion 68 of box extender 20 such as top side 54, bottom side 56, first opposed side 58, and/or second opposed side 60. In the embodiment in FIGS. 1-3, flange 70 extended around the perimeter of box element 20 and the flange portions along top side 54 and bottom side 56 include an opening 57 for allowing access to the retaining openings for fastening the electrical components to box element 20.

Flange edge 72 is substantially aligned with the box edge 34 so that when an electrical box opening is formed in the wall covering, box extender 50 is allowed to be pulled out from box element 20 through the electrical box opening in the wall covering. If outward flange 70 extended substantially beyond box edge 34, then the edge of the wall covering opening would impair easy adjustment outwardly of box extender 50 from box element 20. Attached to flange 70 is a first stop member 80. In this embodiment, first stop member 80 has the shape of a tab pivotally attached to flange 70 at a pivot point 100. First stop member 80, typically, has a length sufficient to not only extend partially along the surface of wall covering 1 but to also be captured against the surface of wall covering 1 by a portion of the electrical component such as the “ears” of an outlet or a switch that typically engage against the surface of wall covering 1 when installed in an electrical box. Alternatively, first stop member 80 may have a friction, pivotal fit to the flange that retains the position of first stop member 80 once positioned against the surface of wall covering 1. It is also contemplated that the thickness of first stop member 80 is only thick enough so that it does not allow box extender 50 to slide into box element 20 beyond the surface of wall covering 1.

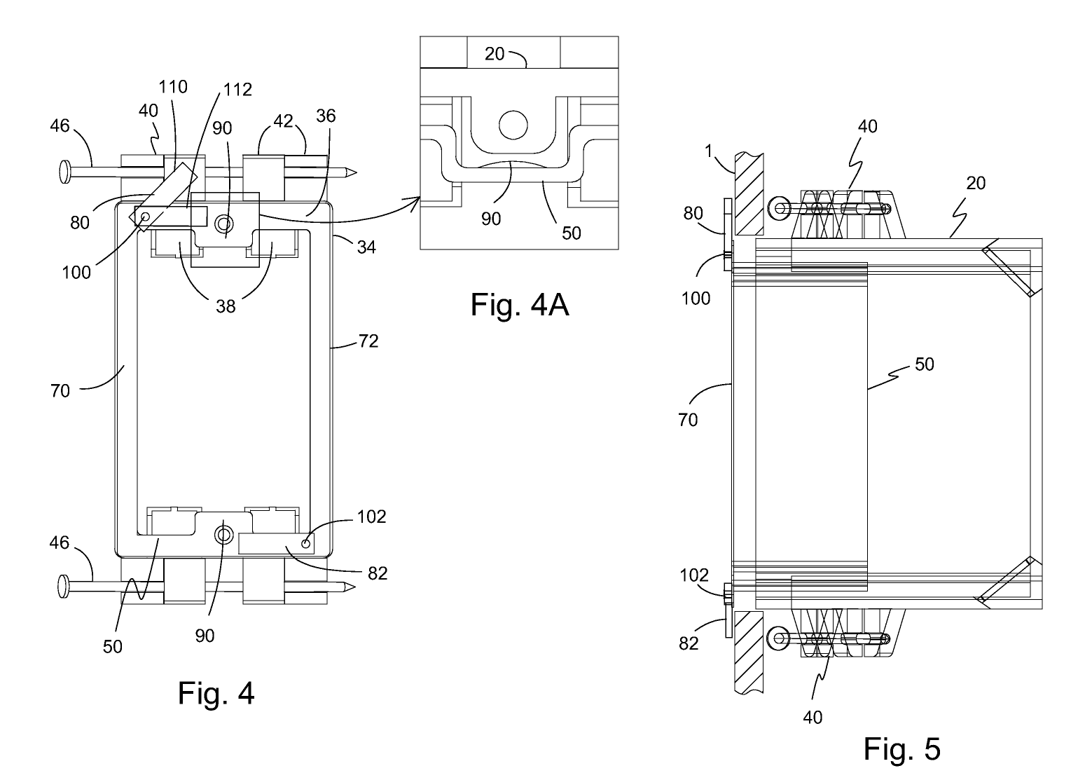

Box extender 50 may also include an optional second stop member 82 similar in structure to first stop member 80 and similarly pivotally attached to flange 70 at a pivot point 102. Although second stop member 82 may be located in any position on flange 70 other than where first stop member 80 is located, it is preferable that second stop member 82 be at a position on flange 70 that is directly opposite and across open front 64 of box extender 20 from the position of first stop member 80. This is more clearly shown in FIG. 4.

Turning now to FIG. 4, there is illustrated a front view of the present invention showing the inside of adjustable electrical box 10 shown in FIG. 1. As previously disclosed, box extender 50 is telescopically received within box element 20 so that first opposed side 58 and second opposed side 60 have a sliding fit with opposed sidewalls 28, 30 of box element 20. As can be seen, the preferred embodiment of box extender 50 has flange edge 72 substantially aligned with box edge 34 while ridge 74 prevents box extender 50 from being inserted into box element 20 beyond front opening 36. Stop members 80, 82 rotate about pivots 100, 102, respectively, from a non-engaging position 110 to a surface-engaging position 112. First stop member 80 illustrates one example of a surface-engaging position while stop member 102 illustrates one example of a non-engaging position. Stop members 80, 82 are typically in the non-engaging position when being installed on the support structure.

Because the adjustable electrical box 10 of the present invention is intended to be installed primarily in new construction, there is a requirement to insure that box extender 50 and box element 20 are maintained together during shipping and installation onto a support structure. Otherwise, box extender 50 could easily become separated from box element 20 and defeating the labor saving advantage of installing the adjustable electrical box 10 over the process of adding a prior art box extender after the wall covering is installed. To accomplish this, a berm 90 is provided on either the outside surface of extender perimeter wall 62 or on the inside surface of box perimeter wall 32. As shown in FIGS. 4 and 4A, berm 90 is located on the outside surface of extender perimeter wall 62. Berm 90 provides a releasable force fit of box extender 50 against an inside surface of box element 20. This prevents the separation of box extender 50 from box element 20 during normal handling and during installation onto the support structure but allows box extender 50 to be easily disengaged from box element 20 by an electrical contractor for adjustment of the electrical box 10 after the wall covering is installed. This saves labor time and expense. It saves labor time because the electrical contractor does not have to obtain a box extender and then install it. Box extender 50 is already in box element 20. It saves cost because each box element 20 will come with box extender 50 leading to larger production runs and lower overall manufacturing, packaging and marketing costs.

It should be understood that the spacing between top side 54 and bottom side 56 of box extender 50 and top wall 24 and bottom wall 26 of box element 20 are exaggerated for illustration purposes to show the detail and/or relationship of berm 90 to box extender 50 and box element 20. It is also noted that berm 90 may be along the sides of box extender 50 or may be an integral part of the inside surface of box element 20. It is important to understand that any other type of component may be used such as tape across the front of box extender 50 and box element 20 that can be later cut after installation of adjustable electrical box 10 to allow adjustment of box extender 50.

Turning now to FIG. 5, there is a side view of the adjustable electrical box 10 and a wall covering 1. As shown, box extender 50 was released from the force-fit or captured position within box element 20 after the wall covering 1 was installed. Box extender 50 is positioned outwardly from box element 20 so that flange 70 of box extender 50 is flush with or slightly beyond the wall covering 1. Stop members 80, 82 are in a surface-engaging position where stop members 80, 82 contact the surface of the wall covering 1 rendering the open front 64 substantially flush with the surface of the wall covering 1.

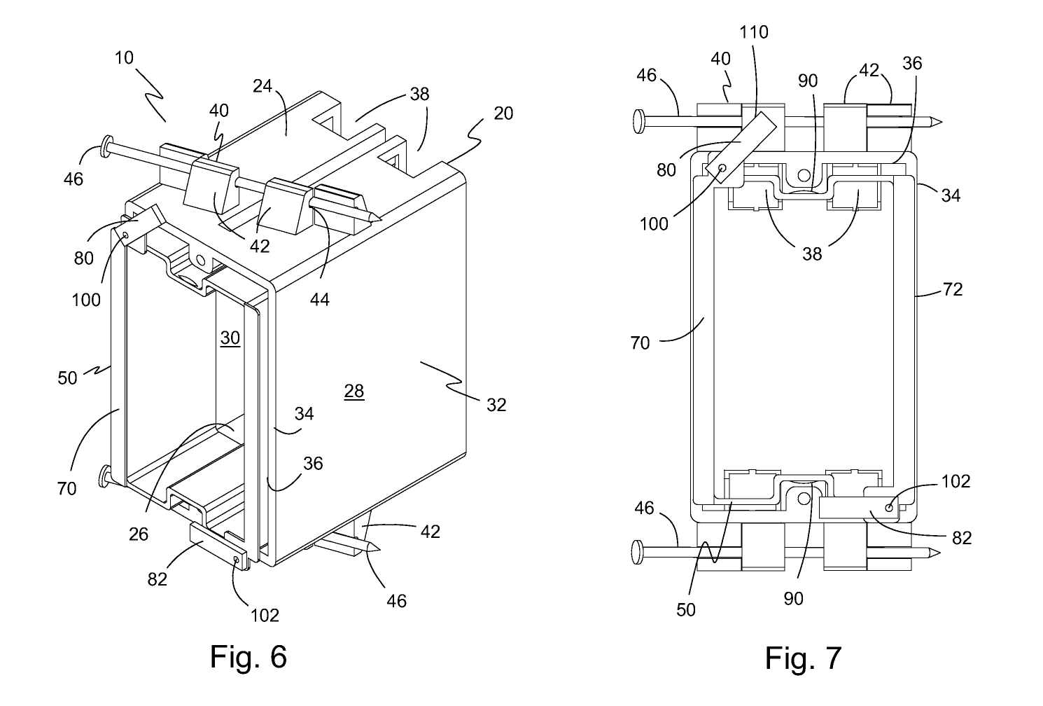

Turning now to FIGS. 6 and 7, there is illustrated another embodiment of the adjustable electrical box 10 of the present invention showing a box extender 50 with a partial flange 70. Box element 20 is the same as and has all of the same reference numbers designating various box element structure as that disclosed in FIG. 1. Box element 20 includes a back wall 22 bounded by a top wall 24, a bottom wall 26, and a pair of opposed sidewalls 28, 30. Top wall 24, bottom wall 26 and opposed sidewalls 28, 30 are joined together to form a continuous perimeter wall 32 ending in a box edge 34. Box edge 34 defines a front opening 36 in to which electrical components and/or wires may extend. Box element 20 may also include a plurality of knock-outs 38 formed on perimeter wall 32.

Box extender 50 is telescopically received within box opening 36. Box extender 50 has a tubular body 52 with top side 54, a bottom side 56, a first opposed side 58, and a second opposed side 60 interconnected to form an extender perimeter wall 62, having a configuration substantially similar to the configuration of the inside surface of perimeter wall 32. Box extender 50 also includes an open front 64 and an open back 66. Perimeter wall 62 has a front portion 68 having a lateral outward flange 70 which ends in a flange edge 72. Flange 70 extends outwardly from a portion of perimeter wall 62 forming a ridge 74. Lateral flange 70 is connected to one or more locations on front portion 68 of box extender 20 such as top side 54, bottom side 56, first opposed side 58, and/or second opposed side 60. In this embodiment, lateral flange 70 extends from first opposed side 58 and second opposed side 60 that are adjacent to opposed sidewalls 28, 30 of box element 20, respectively.

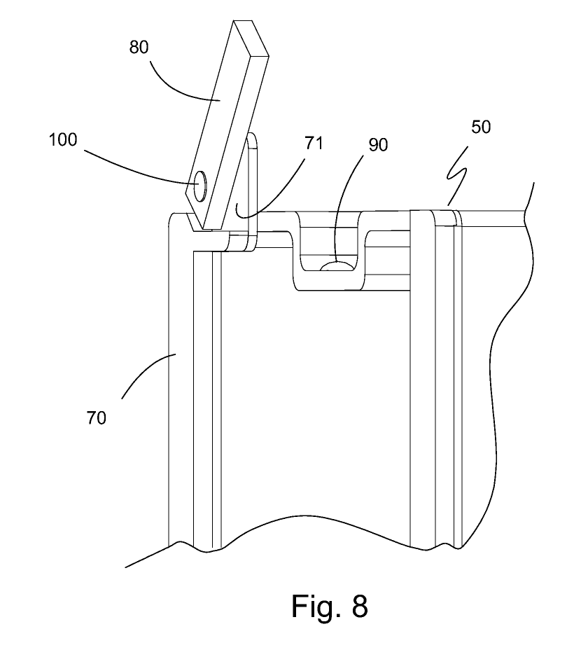

FIG. 8 is an enlarged view of another embodiment of the box extender 50 of the present invention. In this embodiment, box extender 50 has an outwardly extending flange 70 with a recessed flange portion 71. Stop member 80 is pivotally attached to flange 70 at recessed flange portion 71. This configuration allows the outer surface of stop member 80 to be aligned and substantially flush with the outer surface of flange 70.

The method of using the present invention will now be explained. To save labor expense and costs from having to install electrical box extenders after the wall covering is installed, an adjustable electrical box 10 of the present invention is installed on the supporting structure such as the wall framing during construction. A wall covering is installed with openings cutout for exposing adjustable electrical box 10 after wiring is inserted into box element 20 through knockouts 38 in preparation for installing outlets, switches and the like. Because electrical box 10 has box element 20 and box extender 50 telescopically received by and forcibly retained by box element 20, any adjustment of the position of electrical box 10 can be easily made by an electrician or electrical contractor in order meet the code requirements for the particular locale. Particularly, in those locales where a building inspector requires that the electrical box be flush with the wall covering regardless whether the wall covering is made of combustible or non-combustible material, the present invention saves time and costs. After the wall covering is installed, the electrician or electrical contractor need only release box extender 50 from its retained fit with box element 20 and slide box extender 50 outwardly from box element 20 to a point just beyond the surface of wall covering 1. The electrician or electrical contractor then pivots the stop member 80, 82 from their non-engaging position to their surface-engaging position and then pushes box extender 50 into box element 20 until stop members 80, 82 engage against the surface of the wall covering 1. Attaching the outlet, switch and the like to the electrical wiring and the box element 20 prevents box extender 50 from moving outwardly away from the surface of the wall covering 1 while box extender 50 provides a flush fit of the adjustable electrical box 10 with the surface of the wall covering 1.

The combining of the box element 20 and box extender 50 into a single adjustable electrical box 10 for installation in new construction and, particularly, the sliding fit of box extender 50 with box element 20 is important for saving natural resources in the form of electricity, gas, oil, wood, coal, and other energy sources for heating or cooling a room. The sliding fit of the present invention advantageously allows the use of insulating foam sealant in the space between the electrical box 10 and the opening in the wall covering 1 to minimize thermal transfer between the air in the room and outside of the room whether the room is being heated or cooled. The foam sealant also prevents air movement between the inside of the room and the outside of the room through the space between wall covering 1 and electrical box 10. The sliding fit and the substantial alignment of the extender edge 72 and the box edge 34 allows the application of insulating foam sealant in the space between the opening in the wall covering and the box element 20 after installation of the outlet, switch and the like. The sliding fit also prevents any insulating foam sealant from entering the box element 20 when sealing the space between the opening in the wall covering 1 and the adjustable electrical box 10. The present invention also advantageously allows fast adjustment of the box extender 50 without the time-consuming task of turning an adjusting screw to move the box extender 50 in small increments to the final, flush position with the surface of the wall covering, or of possessing a sufficient number of box extenders for installation in those electrical boxes requiring a box extender.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. An adjustable electrical box comprising:
a box element having an enclosure with a box perimeter wall, a back wall and a front opening;
a box extender telescopically received in the box opening, the box extender having a tubular body with an extender perimeter wall, an open front, an open back, and a lateral outward flange connected to a portion of the open front and extending a distance no greater than to the perimeter of the box element; and
a first stop member pivotally connected to the lateral outward flange wherein the first stop member pivots between a first non-engaging position and a second surface-engaging position.

2. The electrical box of claim 1 wherein the lateral outward flange is connected to a portion of one or more locations on the open front of the box extender.

3. The electrical box of claim 2 further comprising a second stop member pivotally connected to the lateral outward flange wherein the second stop element pivots between a first-engaging position and a second non-engaging position, the second stop member being located on a portion of the lateral outward flange that is opposite the position of the first stop member.

4. The electrical box of claim 1 wherein the box element has a berm member located on an inside surface of the box perimeter wall adjacent the front opening wherein the berm member is positioned to provide a releasable interference fit with an outside surface of the extender perimeter wall of the box extender.

5. The electrical box of claim 1 wherein the box extender has a berm member located on an outside surface of the tubular body, the berm member positioned to provide an interference fit with an inside surface of the box element.

6. The electrical box of claim 1 wherein the box extender has a berm member located on one or more of an outside surface selected from the group consisting of a top side, a bottom side, a first opposed side, and a second opposed side.

7. The electrical box of claim 1 wherein the first opposed side and the second opposed side of the box extender has a sliding fit to the pair of opposed sidewalls of the box sufficiently close to allow the application of an insulating foam sealant between the box element and an edge of a surface opening that exposes the opening of the box while minimizing penetration of the insulating foam sealant to the interior of the box element.

8. The electrical box of claim 1 wherein the stop member has an outer surface that aligns with an outer surface of the lateral outward flange.

9. The electrical box of claim 1 wherein the box perimeter wall has a top wall, a bottom wall, a pair of opposed sidewalls, a back wall, and a front opening.

10. The electrical box of claim 1 wherein the extender perimeter wall has a top side, a bottom side, a first opposed side, and a second opposed side.

11. An electrical box extender for being telescopically received into an electrical box, the box extender comprising:
a tubular body, the tubular body with an extender perimeter wall, an open front, an open back, and a lateral outward flange connected to a portion of the open front and extending a distance no greater than to the perimeter of the box element; and
a first stop member pivotally connected to the lateral outward flange wherein the first stop member pivots between a first non-engaging position and a second surface-engaging position.

12. A method for efficiently extending an electrical box opening flush with a wall covering, the method comprising:
providing an electrical box for new construction installation, the electrical box comprising:
a box element forming an enclosure with a front opening;
a box extender telescopically received in the box front opening, the box extender having a tubular body with an extender perimeter wall, an open front, an open back, and a lateral outward flange connected to a portion of the open front and extending a distance no greater than to the perimeter of the box element; and
a first stop member pivotally connected to the lateral outward flange wherein the first stop member pivots between a first non-engaging position and a second surface-engaging position;
attaching the electrical box to a wall framework and installing electrical wiring to the electrical box;
applying a wall covering to the wall framework and creating an opening for exposing the electrical box and electrical wiring;
sliding the box extender outwardly from the box until the lateral outward flange is beyond the surface of the wall covering;
pivoting the first stop member from the first non-engaging position to the second surface-engaging position;
sliding the box extender inwardly into the box until the first stop member engages the surface of the wall covering; and
coupling an electrical component to the electrical wiring and to the electrical box.

13. The method of claim 12 further comprising sealing the space between the electrical box and the edge of the opening in the wall covering with an insulating foam sealant minimizing air and thermal flow between the space behind the wall covering and the room wherein the sliding fit between the box extender and the box element is sufficiently close to minimize the penetration of foam sealant into the box element.

14. The method of claim 12 wherein the step of coupling the electrical component to the electrical box includes coupling the first stop member between a portion of the electrical component and the wall covering.
